(19) United States
(12) Patent Application Publication
(10) Pub. No.: US 2010/0320014 A1
(43) Pub. Date: Dec. 23, 2010

(54) AUTOMOTIVE POWER ELECTRONICS WITH WIDE BAND GAP POWER TRANSISTORS

(75) Inventors: GEORGE R. WOODY, REDONDO BEACH, CA (US); Seok-Joo Jang, Irvine, CA (US); Terence G. Ward, Redondo Beach, CA (US); Stephen J. Hulsey, Los Angeles, CA (US)

Correspondence Address: INGRASSIA FISHER & LORENZ, P.C. (GM), 7010 E. COCHISE ROAD, SCOTTSDALE, AZ, 85253, US

(73) Assignee: GM GLOBAL TECHNOLOGY OPERATIONS, INC., DETROIT, MI (US)

(21) Appl. No.: 12/486,601

(22) Filed: Jun. 17, 2009

(51) Int. Cl. B60L 11/00; H05K 5/00; H05K 7/20; B60K 1/00

(52) U.S. Cl. 180/65.8; 361/752; 361/689

(57) ABSTRACT

An automotive power electronics system is provided. The automotive power electronics system includes a support member and at least one electronic die mounted to the support member. The at least one electronic die has an integrated circuit formed thereon comprising at least one wide band gap transistor.

### TECHNICAL FIELD

The present invention generally relates to power electronics that utilizes wide band gap power semi-conductors for automotive use.

### BACKGROUND OF THE INVENTION

In recent years, advances in technology, as well as ever-evolving tastes in style, have led to substantial changes in the design of automobiles. One of the changes involves the complexity of the electrical systems within automobiles, particularly alternative propulsion vehicles that utilize voltage supplies, such as hybrid, battery electric, and fuel cell vehicles. Such alternative propulsion vehicles typically use one or more electric motors, often powered by direct current (DC) power sources, perhaps in combination with another actuator, to drive the wheels.

Such vehicles often use two separate voltage sources, such as a battery and a fuel cell, to power the electric motors that drive the wheels. Power electronics, such as direct current-to-direct current (DC/DC) converters, are typically used to manage and transfer the DC power from one of the voltage sources and convert to more or less voltage. Also, due to the fact that alternative propulsion automobiles typically include direct current (DC) power supplies, direct current-to-alternating current (DC/AC) inverters (or power inverters) are also provided to invert the DC power to alternating current (AC) power, which is generally required by the motors.

Modern power electronics typically utilize electronic components, such as switches and diodes formed on silicon semiconductor substrates. Such components have undesirable characteristics, including relatively high switching losses when operated at high frequencies (e.g., over 16 kilohertz (kHz)). Additionally, because the operating temperatures of silicon devices differs substantially from some of the other components in the electrical system, multiple cooling systems, or “loops,” must used, which increases the complexity and manufacturing costs of the vehicles.

As the power demands on the electrical systems in alternative fuel vehicles continue to increase, there is an ever increasing need to maximize the electrical efficiency of such systems. There is also a constant desire to reduce the size of the components within the electrical systems in order to minimize the overall cost and weight of the vehicles.

Accordingly, it is desirable to provide power electronics (or a power electronics system) with improved performance characteristics to improve on the undesirable effects of using silicon devices. Furthermore, other desirable features and characteristics of the present invention will become apparent from the subsequent description taken in conjunction with the accompanying drawings and the foregoing technical field and background.

### SUMMARY OF THE INVENTION

An automotive power electronics system is provided. The automotive power electronics system includes a support member and at least one electronic die mounted to the support member. The at least one electronic die has an integrated circuit formed thereon comprising at least one wide band gap transistor.

An automotive power electronics propulsion system is provided. The automotive power electronics propulsion system includes a support member and a plurality of electronic die mounted to the support member. Each electronic die includes a substrate having an integrated circuit formed thereon. The substrate of each electronic die includes a wide band gap semiconductor material, and each integrated circuit includes at least one wide band gap transistor.

An automotive propulsion system is provided. The automotive system includes an electric motor, at least one direct current (DC) power supply, a power inverter coupled to the electric motor and the at least one DC power supply, and a controller in operable communication with power inverter and coupled to the electric motor and the at least one DC power supply. The power inverter includes a support member and at least one electronic die mounted to the support member. The at least one electronic die has an integrated circuit formed thereon including at least one wide band gap transistor. The controller is configured to operate the at least one wide band gap transistor.

### DESCRIPTION OF THE DRAWINGS

The present invention will hereinafter be described in conjunction with the following drawing figures, wherein like numerals denote like elements, and

FIG. 1 is a schematic view of an exemplary automobile according to one embodiment of the present invention;

FIG. 2 is a schematic view of a direct current-to-direct current (DC/DC) power converter system within the automobile of FIG. 1;

FIG. 3 is a schematic view of a direct current-to-alternating current (DC/AC) power inverter system within the automobile of FIG. 1;

FIG. 4 is a cross-sectional side view of a wide band gap semiconductor substrate having a transistor formed thereon according to one embodiment of the present invention; and

FIGS. 5 a schematic view of a single loop cooling system according to one embodiment of the present invention.

### DESCRIPTION OF AN EXEMPLARY EMBODIMENT

The following detailed description is merely exemplary in nature and is not intended to limit the invention or the application and uses of the invention. Furthermore, there is no intention to be bound by any expressed or implied theory presented in the preceding technical field, background, and brief summary, or the following detailed description.

The following description refers to elements or features being “connected” or “coupled” together. As used herein, “connected” may refer to one element/feature being mechanically joined to (or directly communicating with) another element/feature, and not necessarily directly. Likewise, “coupled” may refer to one element/feature being directly or indirectly joined to (or directly or indirectly communicating with) another element/feature, and not necessarily mechanically. However, it should be understood that although two elements may be described below, in one embodiment, as being “connected,” in alternative embodiments similar elements may be “coupled,” and vice versa. Thus, although the schematic diagrams shown herein depict example arrangements of elements, additional intervening elements, devices, features, or components may be present in an actual embodiment.

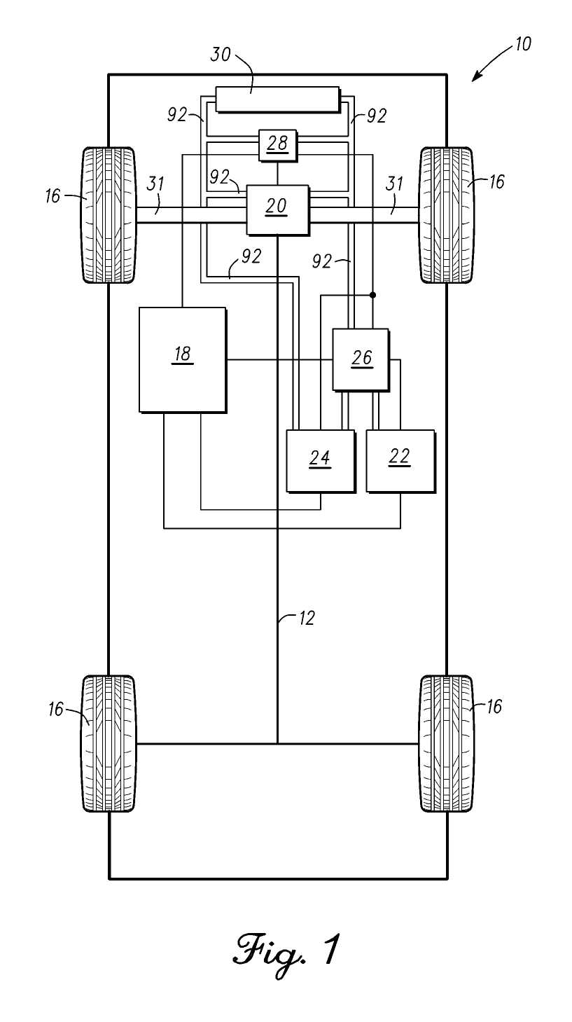

Further, various components and features described herein may be referred to using particular numerical descriptors, such as first, second, third, etc., as well as positional and/or angular descriptors, such as horizontal and vertical. However, such descriptors may be used solely for descriptive purposes relating to drawings and should not be construed as limiting, as the various components may be rearranged in other embodiments. It should also be understood that FIGS. 1-5 are merely illustrative and may not be drawn to scale.

FIG. 1 to FIG. 5 illustrate an automotive power electronics system according to one embodiment of the present invention. The automotive power electronics system includes a support member and at least one electronic die mounted to the support member. The electronic die has an integrated circuit formed thereon including at least one wide band gap transistor. The automotive power electronics system may be, for example, a direct current-to-direct current (DC/DC) power converter or a direct current-to-alternating current (DC/AC) inverter. The electronic die may include a semiconductor substrate including a wide band gap semiconductor material, such as gallium nitride (GaN), silicon carbide (SiC), or a combination thereof. The use of the wide band gap semiconductor material in the transistor allows for an increase in operating frequencies when compared with conventional silicon based devices without high switching losses, as well as the use of a single “loop” cooling system to regulate the temperature of various electrical components in a vehicle.

FIG. 1 illustrates a vehicle, or automobile 10, according to one embodiment of the present invention. The automobile 10 includes a chassis 12, a body 14, four wheels 16, and an electronic control system 18. The body 14 is arranged on the chassis 12 and substantially encloses the other components of the automobile 10. The body 14 and the chassis 12 may jointly form a frame. The wheels 16 are each coupled to the chassis 12 near a respective corner of the body 14.

The automobile 10 may be any one of a number of different types of automobiles, such as, for example, a sedan, a wagon, a truck, or a sport utility vehicle (SUV), and may be two-wheel drive (2WD) (i.e., rear-wheel drive or front-wheel drive), four-wheel drive (4WD), or all-wheel drive (AWD). The automobile 10 may also incorporate any one of, or combination of, a number of different types of engines, such as, for example, a gasoline or diesel fueled combustion engine, a “flex fuel vehicle” (FFV) engine (i.e., using a mixture of gasoline and alcohol), a gaseous compound (e.g., hydrogen and/or natural gas) fueled engine, a combustion/electric motor hybrid engine (i.e., such as in a hybrid electric vehicle (HEV)), and an electric motor.

In the exemplary embodiment illustrated in FIG. 1, the automobile 10 is a fuel cell vehicle, and further includes an electric motor/generator 20, a battery 22, a fuel cell power module (FCPM) 24, a DC/DC converter system 26, a DC/AC inverter 28, and a heat exchanger (or radiator) 30. Although not illustrated, the electric motor/generator 20 (or motor) includes a stator assembly (including conductive coils), a rotor assembly (including a ferromagnetic core), and a cooling fluid (i.e., coolant), as will be appreciated by one skilled in the art. The motor 20 may also include a transmission integrated therein such that the motor 20 and the transmission are mechanically coupled to at least some of the wheels 16 through one or more drive shafts 31.

As shown, the battery 22 and the FCPM 24 are in operable communication and/or electrically connected to the electronic control system 18 and the DC/DC converter system 26. Although not illustrated, the FCPM 24, in one embodiment, includes, amongst other components, a fuel cell having an anode, a cathode, an electrolyte, and a catalyst. As is commonly understood, the anode, or negative electrode, conducts electrons that are freed from, for example, hydrogen molecules so that they can be used in an external circuit. The cathode, or positive electrode (i.e., the positive post of the fuel cell), conducts the electrons back from the external circuit to the catalyst, where they can recombine with the hydrogen ions and oxygen to form water. The electrolyte, or proton exchange membrane, conducts only positively charged ions while blocking electrons. The catalyst facilitates the reaction of oxygen and hydrogen.

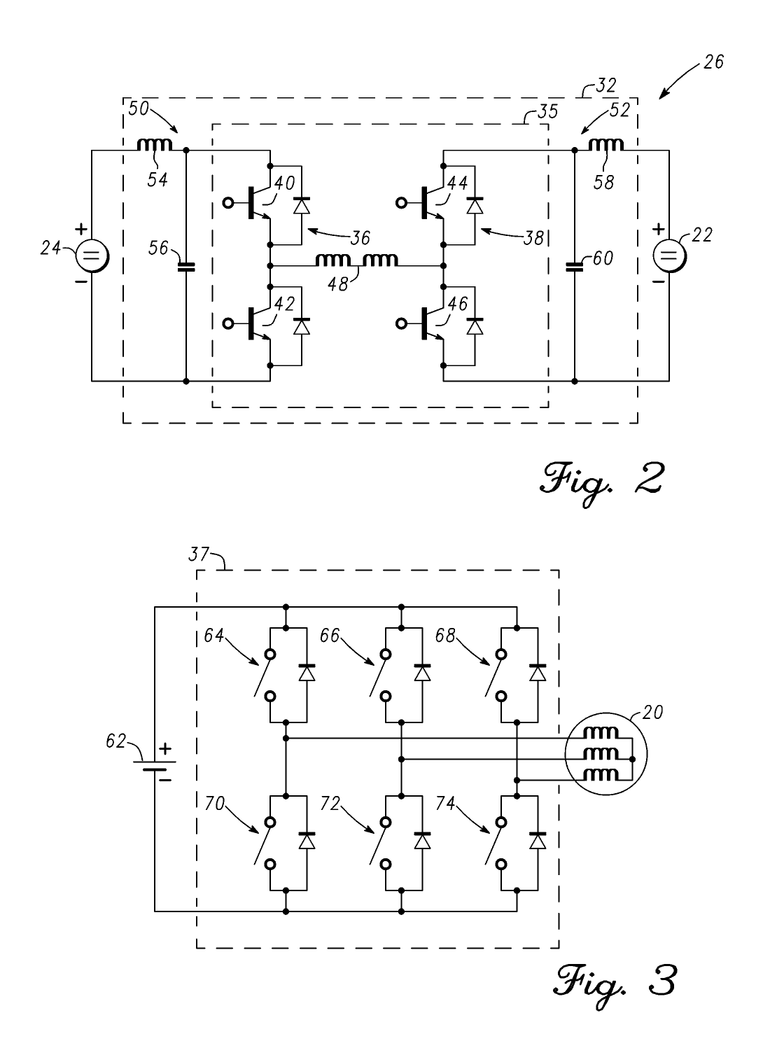

FIG. 2 schematically illustrates the DC/DC converter system 26 in greater detail, in accordance with an exemplary embodiment of the present invention. In the depicted embodiment, the DC/DC converter system 26 includes a bi-directional DC/DC converter (BDC) 32 coupled to the FCPM 24 and the battery 22. The BDC converter 32, in the depicted embodiment, includes a converter support member (e.g., a frame or substrate) 35 and a power switching section with two dual field effect transistor (FET) legs 36 and 38, each having two FETs, 40 and 42, and 44 and 46, respectively, connected or mounted to the converter support member 35. The two legs 36 and 38 are interconnected at midpoints by an inductor (or inductors, as described below) 48. The BDC converter 32 also includes a first filter 50 connected to the positive rail of the first FET leg 36 and a second filter 52 connected to the positive rail of the second FET leg 38. As shown, the filters 50 and 52 include a first inductor 54, a first capacitor 56, a second inductor 58, and a second capacitor 60, respectively. The first FET leg 36 is connected to the FCPM 24 through the first filter 50, and the second FET leg 38 is connected to the battery 22 through the second filter 52. As shown, the FCPM 24 and the battery are not galvanically isolated, as the negative (−) terminals are electrically connected.

Although not shown, the DC/DC converter system 26 may also include a BDC controller in operable communication with the BDC converter 32. The BDC controller may be implemented within the electronic control system 18 (FIG. 1), as is commonly understood in the art. It should also be understood that although a bi-directional converter is shown, other embodiments may utilize uni-directional converters, as will be appreciated one skilled in the art.

FIG. 3 schematically illustrates the DC/AC inverter 28 in greater detail, in accordance with an exemplary embodiment of the present invention. The inverter 28 includes an inverter support member 37 and a three-phase circuit connected or mounted to the inverter support member 37 and coupled to the motor 20. More specifically, the inverter 28 includes a switch network having a first input coupled to a voltage source 62 (e.g., the battery 22 and/or the FCPM 24 through the DC/DC converter system 26 and an output coupled to the motor 20). Although a single voltage source is shown, a distributed direct current (DC) link with two series voltage sources may be used.

The switch network comprises three pairs of series switches (e.g., FETs) with antiparallel diodes (i.e., antiparallel to each switch) corresponding to each of the phases. Each of the pairs of series switches comprises a first switch, or transistor, (i.e., a “high” switch) 64, 66, and 68 having a first terminal coupled to a positive electrode of the voltage source 62 and a second switch (i.e., a “low” switch) 70, 72, and 74 having a second terminal coupled to a negative electrode of the voltage source 62 and having a first terminal coupled to a second terminal of the respective first switch 64, 66, and 68.

Although not shown, the DC/AC inverter 28 may also include an inverter control module, which may be implemented within the electronic control system 18 (FIG. 1), as is commonly understood in the art.

The BDC 32 and the inverter 28 may also include a plurality of power module devices, each including a semiconductor substrate, or a plurality of (i.e., one or more) electronic die, each with an integrated circuit formed thereon, amongst which the switches 40-46 and 64-74 are distributed, as is commonly understood.

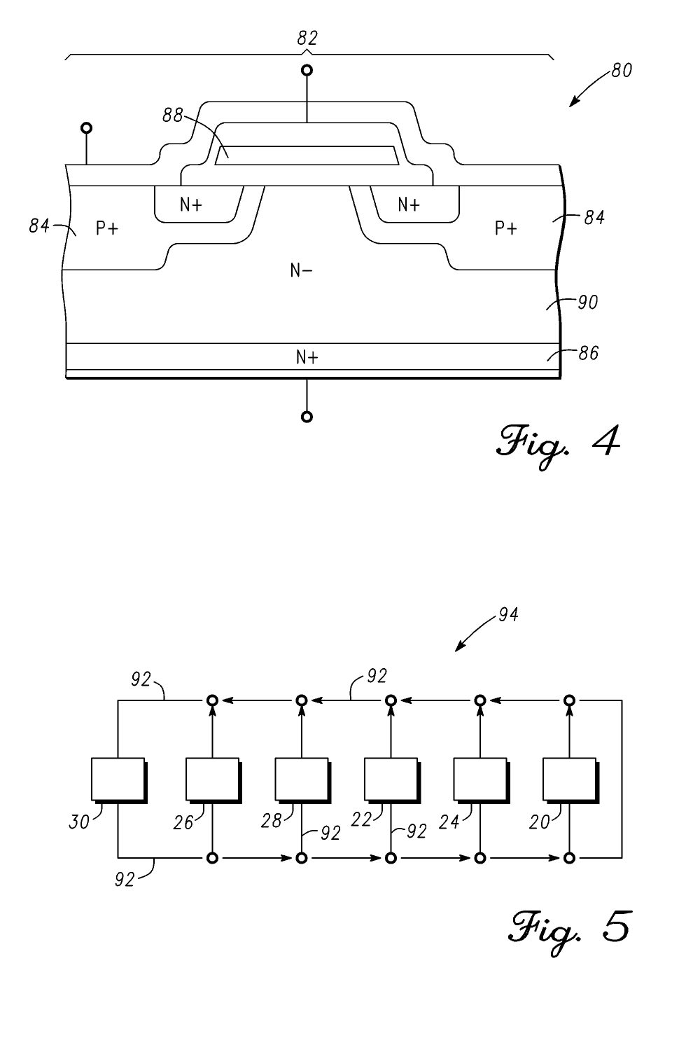

FIG. 4 illustrates a semiconductor substrate 80 which may be implemented in the BDC 32 and/or the inverter 28, in accordance with one embodiment of the present invention. In accordance with one aspect of the present invention, the semiconductor substrate 80 includes a wide band gap semiconductor material (e.g., with an electronic band gap of greater than 1 electron volt (eV)), as is commonly understood. The semiconductor material used may be gallium nitride (GaN), silicon carbide (SiC), and/or any combination thereof. It should be noted that in some embodiments, the substrate 80 may include other materials besides the wide band gap material. For example, the substrate may include a layer of the wide band gap material formed over a substrate made of, for example, silicon or sapphire.

The semiconductor substrate 80 includes a high electron mobility transistor (HEMT), such as a FET 82, as is commonly understood, formed thereon. In the depicted embodiment, the FET 82 includes, amongst other components, conductive emitter regions (e.g., having a P-dopant type) 84 formed in a first surface (e.g., upper surface) of the substrate 80, a conductive collector layer (e.g., having a N+-dopant type) 86 formed in a second surface (e.g., a lower surface) of the substrate 80, and a conductive gate 88 formed over the first surface and extending between the emitter regions 84. An epitaxial drift region (e.g., having an N-dopant type) 90 interconnects the emitter regions 84 and the collector layer (or substrate) 86, as shown in FIG. 4. Although only one FET 82 is shown, it should be understood that the semiconductor substrate 80 may include multiple such FETs formed on portions of the semiconductor substrate 80 that are not shown. It should also be understood that multiple semiconductor substrates 80 (and/or electronic die) may be used to form each of the switches 40-46 and 64-74 shown in FIGS. 2 and 3 and described above. It should be noted that although the example shown is a vertical type structure switch, the wide band gap devices also be formed as lateral structures in which the gate, drain, and source are all on one side (e.g., the top side) of the substrate.

Referring again to FIG. 1, the heat exchanger 30 is connected to the frame at an outer portion thereof and although not illustrated in detail, includes multiple cooling channels therethough that contain a cooling fluid (i.e., coolant) such as water and/or ethylene glycol (i.e., “antifreeze). The heat exchanger 30 (and/or the cooling channels therein) is in fluid communication with the inverter 28, the electric motor 20, the BDC 26, the battery 22, and the FCPM 24 through a plurality of fluid conduits 92.

FIG. 5 illustrates, in a simplified schematic fashion, a cooling system 94 that may be implemented within the automobile 10 using the heat exchanger 30 and the components in fluid communication with the heat exchanger 30. As indicated, and will be appreciated by one skilled in the art, in the cooling system 94 shown in FIG. 5, the BDC 26, the inverter 28, the battery 22, the FCPM 24, and the electric motor 20 are in fluid communication with the heat exchanger 30 in a “single loop” configuration through the fluid conduits 92. That is, each of the BDC 26, the inverter 28, the battery 22, the FCPM 24, and the electric motor 20 are in direct fluid communication with the heat exchanger 30, while also being in direct fluid communication with each other. In other words, the fluid conduits 92 form fluid passageways between each of the BDC 26, the inverter 28, the battery 22, the FCPM 24, and the electric motor 20, which allows fluid to flow through the heat exchanger 30.

Referring again to FIG. 1, the electronic control system 18 is in operable communication with the motor 20, the battery 22, the FCPM 24, the DC/DC converter system 26, and the inverter 28. Although not shown in detail, the electronic control system 18 includes various sensors and automotive control modules, or electronic control units (ECUs), such as the BDC controller, the inverter control module, and a vehicle controller, and at least one processor and/or a memory which includes instructions stored thereon (or in another computer-readable medium) for carrying out the processes and methods as described below. Although not shown, in other embodiments separate controllers may be integrated at each of the converter and inverter.

During operation, still referring to FIG. 1, the automobile 10 is operated by providing power to the wheels 16 with the electric motor 20 using power from the battery 22 and FCPM 24 in an alternating manner and/or with the battery 28 and the electric motor 20 simultaneously using the inverter 28 and/or the BDC 26, in a known manner.

One advantage of the use of the wide band gap transistors is that the frequencies at which the inverter 28 and/or the BDC 26 is operated may be significantly increased when compared to conventional silicon based transistors, while providing improved efficiency. For example, in one simulation, gallium nitride based transistors operated at both 10 kilohertz (kHz) and 100 kHz demonstrated an improvement in efficiency when compared to silicon based transistors operated at 10 kHz. The increased frequency of operation of the inverter 28 reduces the ripple current in the AC waveform that is provided to the electric motor 20 which improves the efficiency of the electric motor 20, when compared to lower frequency operation of the inverter when using conventional silicon based transistors, which reduces power consumption, and in the case of a hybrid electric vehicle, decreases fuel consumption.

Another advantage is that because of the increased operating frequencies, smaller and lighter components may be used in the inverter 28 and/or the BDC. For example, the mass of the converter inductor (e.g., inductor 48) used in the BDC 26 may be reduced as the frequency is increased when compared to that used in a converter using conventional silicon transistors. As a result, manufacturing costs are reduced, and power consumption is even further decreased.

A further advantage is that because the wide band gap operate at temperatures higher than conventional silicon based transistors, a single loop cooling system, such as that shown in FIG. 5, may be used. As a result, manufacturing costs are even further reduced, as is power consumption.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. An automotive power electronics system comprising;
a support member; and
at least one electronic die mounted to the support member, the at least one electronic die having an integrated circuit formed thereon comprising at least one wide band gap transistor.

2. The automotive power electronics system of claim 1, wherein the at least one electronic die comprises a substrate, the substrate comprising a wide band gap semiconductor material.

3. The automotive power electronics system of claim 2, wherein the wide band gap semiconductor material has an electronic band gap greater than 1 electron volt (eV).

4. The automotive power electronics system of claim 3, wherein the wide band gap semiconductor material comprises gallium nitride, silicon carbide, or a combination thereof.

5. The automotive power electronics system of claim 4, further comprising at least one diode mounted to the support member and coupled to the at least one wide band gap transistor.

6. The automotive power electronics system of claim 5, wherein the automotive power inverter is a direct current-to-alternating current (DC/AC) power inverter.

7. The automotive power electronics system of claim 5, wherein the automotive power electronics is a direct current-to-direct current (DC/DC) power converter.

8. The automotive power electronics system of claim 7, further comprising an inductor coupled to the at least one wide band gap transistor.

9. An automotive power electronics propulsion system comprising:
a support member; and
a plurality of electronic die mounted to the support member, each electronic die comprising a substrate having an integrated circuit formed thereon, the substrate of each electronic die comprising a wide band gap semiconductor material and each integrated circuit comprising at least one wide band gap transistor.

10. The automotive power electronics propulsion system of claim 9, further comprising at least one diode mounted to the support member and coupled to the at least one wide band gap transistor.

11. The automotive power electronics propulsion system of claim 10, wherein the at least one transistor is a field effect transistor (FET).

12. The automotive power electronics propulsion system of claim 11, wherein the wide band gap semiconductor material comprises gallium nitride, silicon carbide, or a combination thereof.

13. The automotive power electronics propulsion system of claim 12, wherein the automotive power electronics is a direct current-to-alternating current (DC/AC) power inverter.

14. The automotive power electronics propulsion system of claim 13, wherein the automotive power electronics is a direct current-to-direct current (DC/DC) power converter.

15. The automotive power electronics propulsion system of claim 14, further comprising an inductor coupled to the at least one wide band gap transistor.

16. An automotive propulsion system comprising:
an electric motor;
at least one direct current (DC) power supply;
a power inverter coupled to the electric motor and the at least one DC power supply, the power inverter comprising:
a support member; and
at least one electronic die mounted to the support member, the at least one electronic die having an integrated circuit formed thereon comprising at least one wide band gap transistor; and
a controller in operable communication with the power inverter and coupled to the electric motor and the at least one DC power supply, the controller being configured to operate the at least one wide band gap transistor.

17. The automotive propulsion system of claim 16, further comprising a heat exchanger being in fluid communication with the at least one DC power supply and at least one of the electric motor and the power inverter through a plurality of fluid conduits.

18. The automotive propulsion system of claim 17, wherein the at least one DC power supply and the at least one of the electric motor and the power inverter are in fluid communication through the plurality of fluid conduits such that a flow path is formed between the at least one DC power supply and the at least one of the electric motor and the power inverter without passing through the heat exchanger.

19. The automotive propulsion system of claim 18, wherein the at least one DC power supply comprises a fuel cell.

20. The automotive propulsion system of claim 19, wherein the at least one electronic die comprises a substrate, the substrate comprising gallium nitride, silicon carbide, or a combination thereof.
